(19) United States
(12) Patent Application Publication
(10) Pub. No.: US 2025/0265220 A1
(43) Pub. Date: Aug. 21, 2025

(54) MULTI-CHIP MODULE PACKAGE TECHNOLOGY FOR ADVANCED DRIVER ASSISTANCE SYSTEM APPLICATION

(71) Applicant: Rivian IP Holdings, LLC, Irvine, CA (US)

(72) Inventors: Mengzhi PANG, Cupertino, CA (US); Mukund Tejkumar CHAVAN, Fremont, CA (US); Seu Wah LOW, San Jose, CA (US); Xiaojin WEI, Dublin, CA (US); Marcus Hwai Yik TAN, Union City, CA (US); Zijie CAI, Irvine, CA (US); Shiji PAN, Irvine, CA (US); Jiangong WEI, San Diego, CA (US); Adrian JAVELO, Campbell, CA (US)

(21) Appl. No.: 19/053,229

(22) Filed: Feb. 13, 2025

Related U.S. Application Data
(60) Provisional application No. 63/554,082, filed on Feb. 15, 2024.

(51) Int. Cl. G06F 15/78

(52) U.S. Cl. CPC G06F 15/7821

(57) ABSTRACT

Aspects of the disclosure relate to automotive grade MCM technology which may include advanced driver assistance system (ADAS) system-on-chip and multiple dynamic random access memories (DRAMs) in one package. In addition, a thermal-mechanical testing vehicle (TMTV) may be used to mimic ADAS chips on ADAS system from thermal, mechanical, or manufacturability perspective. There may be a system which includes multiple MCM components designed into a customized printed circuit board (PCB) with a liquid cooling system.

### CROSS REFERENCE TO RELATED APPLICATION(S)

The present application claims the benefit of U.S. Provisional Application No. 63/554,082 entitled “MULTI-CHIP-MODULE PACKAGE TECHNOLOGY FOR ADAS APPLICATION” filed Feb. 15, 2024, the entirety of which is incorporated herein for reference.

### INTRODUCTION

A multi-chip module (MCM) is generically an electronic assembly (such as a package with a number of conductor terminals or “pins”) in which multiple integrated circuits (ICs or “chips”), semiconductor dies, or other discrete components may be integrated, usually onto a unifying substrate, so that in use, the MCM may be treated as if it were a larger IC. MCM packaging may allow a manufacturer to use multiple components for modularity or to improve yields over a conventional monolithic IC approach. In addition, certain ICs have very similar or identical pinouts when used multiple times within systems. A carefully designed substrate may allow these dies to be stacked in a vertical configuration making the resultant footprint of the MCM smaller, since area may be at a premium in miniature electronics designs.

Integrated circuits, packaged or unpackaged, may be subjected to environmental testing as an operation in a manufacturing process. In such testing, the integrated circuit devices may be subject to electrical testing, e.g., “test patterns,” to confirm functionality while being subjected to environmental stress. For example, an integrated circuit may be heated or cooled to its specification limits while being electrically tested. In some cases, e.g., for qualification testing, an integrated circuit may be stressed beyond its specifications, for example, to determine failure points or establish guard band on its environmental specifications.

Aspects of the subject technology can help to improve the overall cost, reliability, and efficiency of circuits or other electronic components.

### SUMMARY

The present description is generally directed to automotive grade MCM technology which may include advanced driver assistance system (ADAS) system-on-chip (SoC) and multiple dynamic random access memories (DRAMs) in one package. In addition, a thermal-mechanical testing vehicle (TMTV) may be used to mimic ADAS chips on ADAS system from thermal, mechanical, or manufacturability perspective. There may be a system which includes multiple MCM components designed into a customized printed circuit board (PCB) with liquid cooling system.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates example views of multi-chip-module (MCM) that may include an ADAS system-on-chip (SoC) and multiple DRAMs co-packaged.

FIG. 2A illustrate an example side cross-sectional view of chip packaging technology on a substrate.

FIG. 2B illustrate an example side cross-sectional view of chip packaging technology on a substrate.

FIG. 3 illustrates an example MCM and Lid.

FIG. 4A illustrates an example MCM with TIM consideration.

FIG. 4B illustrates an example MCM with TIM consideration.

FIG. 5A illustrates an example liquid cooling configuration associated with TMTV.

FIG. 5B illustrates an example board associated with TMTV.

FIG. 6 illustrates an example TMTV design feature summary.

FIG. 7 illustrates an example die crack sensor configuration.

FIG. 8 illustrates example capacitor related TMTV design features.

FIG. 9 illustrates an example corner bump and stack via related to TMTV design features.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, the subject technology is not limited to the specific details set forth herein and can be practiced using one or more other implementations. In one or more implementations, structures and components are shown in block diagram form in order to avoid obscuring the concepts of the subject technology.

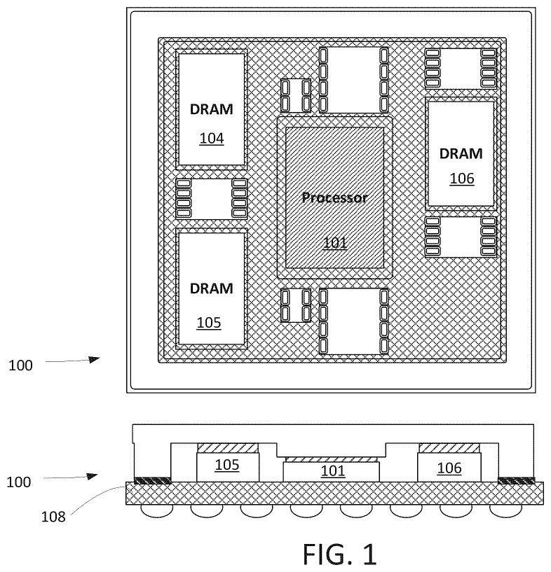

As shown in FIG. 1, multi-chip-module (MCM) 100 may include processor 101 (e.g., an ADAS SoC) and multiple DRAMs (e.g., DRAM 104, DRAM 105, or DRAM 106) co-packaged with processor 101, which may allow for, at ADAS system level, enabling of double data rate (DDR) bandwidth requirements, enable reduced cost, increased power delivery, or further optimizations. FIG. 1 displays three DRAMs, but there may be any appropriate number of DRAMs that around processor 101. The number of DRAMs implemented may be based on a memory bandwidth requirement (e.g., memory bandwidth (BW) requirement of ADAS SoC in consideration of available DRAMs).

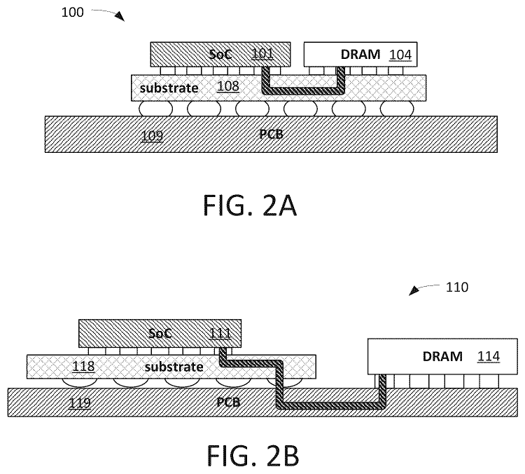

The disclosed MCM may allow for critically enabled DDR bandwidth requirement of ADAS SoC by ensuring data rate (e.g., LPDDR5x 8.5 gbps) with ensured signal and power quality which may otherwise be challenging to achieve if DRAM is integrated at board level. This in turn may help save DRAM related system cost, which may include the assumption that the same total bandwidth is required regardless of DRAM integration scheme (co-package or on board), if MCM subject matter, as illustrated in FIG. 2, is implemented. FIG. 2A and FIG. 2B illustrate an example comparison of MCM and Flip-Chip Ball Grid Array (FCBGA). FIG. 2A illustrate example side cross-sectional views of chip packaging technology on a substrate. MCM 100 may include printed circuit board (PCB) 109, substrate 108, processor 101 (e.g., SoC 101), or memory 104 (e.g., DRAM 104). As shown in FIG. 2, processor 101 and memory 104 may be on the same substrate 108 and may be connected therethrough such substrate 108. FIG. 2B illustrate example side cross-sectional views of chip packaging technology on a PCB. As shown in FIG. 2B, MCM 110 may include PCB 119, substrate 118, processor 111 (e.g., SoC 111), or memory 114 (e.g., DRAM 104). As shown in FIG. 2, processor 111 may be on substrate 118 and memory 114 may be on PCB 119. The connection between process 111 and memory 114 may be connected through at least substrate 118 and PCB 119.

The disclosed MCM 100 may help enable a reduced cost and more efficient power delivery of ACM3 system due to one or more of the following three considerations. A first consideration may be that high density DRAM signal routing may be executed on MCM 100 instead of on PCB, thus a standard through hole printed circuit board (PCB) instead of a higher-cost micro via type may be applied to save cost. A second consideration may be that smaller PCB area, and smaller system cold plate form factor may be enabled by DRAM 104 on package MCM architecture. The form factor reduction opportunity may be a significant percentage (e.g., approximately 70% or more) combined footprint reduction (vs. So+DRAMs on board). Board design may be simplified without DDRs and system level bring-up with SoC/DRAM as incoming known good units. A third consideration may be that there may be better power delivery (e.g., reduced power related noise), due to customized MCM ball grid array (ball pitch and ball map) to help optimize PCB backside cap placement, and there may be an elimination of DRAM routing on PCB 109 induced inferior power delivery plane, as well as much closer power management integrated circuit (PMIC) to SoC key IP point of load to reduce IR drop. In an example, an overall power related noise range reduction may be over 50%, worst voltage drop reduction may be over 50%, DC resistance may be reduced by over 30%, or alternating current inductance (ACI) may be reduced by over 40% when considering other packaging technology such as MCM 110.

In addition to SoC die, package or PCB floor plan, among other things may be optimized for overall system level performance. In an example, there may be core IP placement at die edge beach front to ensure direct access to die side capacitors for fast di/dt transient response of power delivery network, as well as close access to PMIC placed on PCB.

The disclosed subject matter may be associated with automotive grade MCM technology that may include ADAS SoC 101 and multiple DRAMs 104 in one package. The multi-chip-module (MCM) 100 may integrate DRAMs 104 with SoC 101 as one integral ball grid array component for an application, such as autonomous driving application, as disclosed herein.

As disclosed, DRAMs 104 may be placed around a SoC 101. The more symmetrical the configuration, such as in a “butterfly” floor plan, the increased possibility of more unified warping, if warping occurs. Each SoC PHY to DRAM design and signal/power performance may be repeated across multiple instances so as to provide predictable system level performance when multiple DRAMs operate under various user conditions. SoC at an approximately central location in package floor plan may help to save ˜3-5 C Tjunction max (Tjmax) at critical IPs, such as machine learning engine, and thus may help to improve performance or save power. This structure may be mechanically balanced, which may lead to uniform warpage distribution so as to help a robust surface-mount technology (SMT) process when assembled on PCB 109.

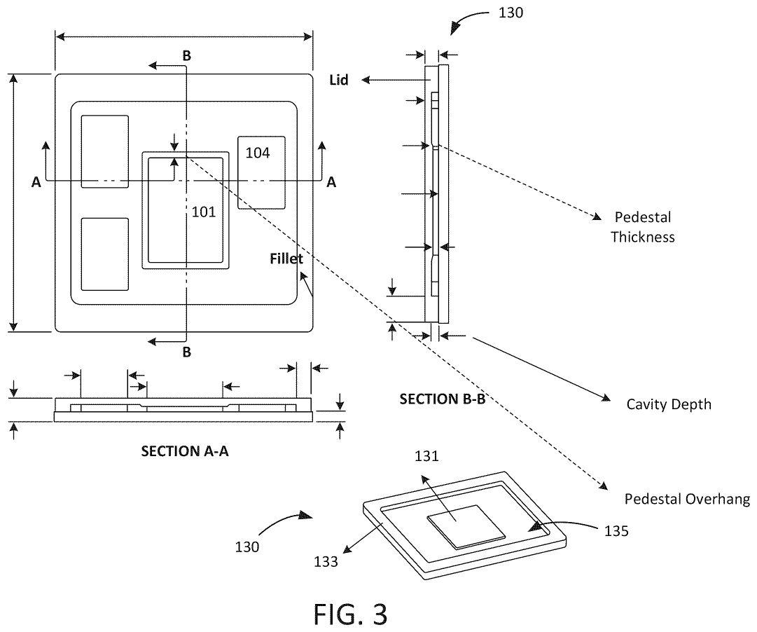

FIG. 3 illustrates an example thermal lid 130 that may be incorporated with MCM 100. Thermal lid 130 may include a pedestal 131, landing 133, or cavity 135. Thermal lid 130 may be made of Nickel plated Copper (Ni plated Cu) with pedestal design, as shown in FIG. 3. Thermal lid 130 may be fabricated from copper (Cu) that has been electroplated with nickel (Ni). Copper may serve as the primary structural material due to its thermal conductivity (approximately 385 W/m·K at room temperature) and mechanical properties, while the nickel plating may provide surface protection against oxidation or corrosion. The nickel plating thickness may be employed based on specific application requirements. Thermal lid 130 may alternatively be constructed from other thermally conductive materials, such as aluminum (Al), copper-tungsten (Cu-W), copper-molybdenum (Cu-Mo), or other suitable metals or metal alloys with appropriate thermal or mechanical properties for semiconductor package applications. Table 1 illustrates example considerations associated with thermal lid 130.

TABLE 1

| Parameter | Mechanical/Assembly | Thermal |
|---|---|---|
| Pedestal Thickness | It may help ensure | |
| (e.g., approximately | DRAM TIM BLT in | |
| .50 mm) | range acceptable to | |
| | assembly (150 um to | |
| | 400 umm). | |
| | Thicker pedestal | |
| | thickness → thicker lid | |
| | landing → larger | |
| | adhesive delam risk. | |
| Cavity Depth (e.g., | Achieve target SoC TIM | Tjmax may be reduced |
| approximately | BLT (e.g., 65 um) | (e.g., by approximately |
| 1.25 mm or 1.2 | without lid contacting | 1.3° C.) for every TIM |
| mm) | substrate first, e.g., | BLT reduction (e.g., |
| | adhesive thickness | 10 um) |
| | decreases to filler size | |
| Pedestal Overhang | Overhang may | Thermal gain of (e.g., |
| (e.g., approximately | accommodate placement | approximately 0.6 C and |
| 1 mm or 2.5 mm) | tolerance Upper bound | 1.3 C) when overhang is |
| | determined by overhang | of a certain measurement |
| | to DRAM assembly | (e.g., approximately 1 |
| | spacing requirement | mm and 2.5 mm, |
| | | respectively). |

The disclosed pedestal configuration of thermal lid 130 may address inefficiencies based on SoC silicon and DRAM component Z height difference. As shown, pedestal 131 may be placed above SoC 101 or the DRAM 104, whichever is shortest (usually SoC 101) or multiple components (e.g., one or more DRAMs 104, 105, 106 and SoC 101), if preferred. In an example, where SoC 101 has a significant cavity (e.g., cavity 135), there may be a desire to reduce the size of cavity 135 between thermal lid 130 and SoC 101. Therefore, thermal lid 130 may be created with pedestal 131 (e.g., pedestal overhang or protrusion) associated with thermal lid 130, which may improve performance.

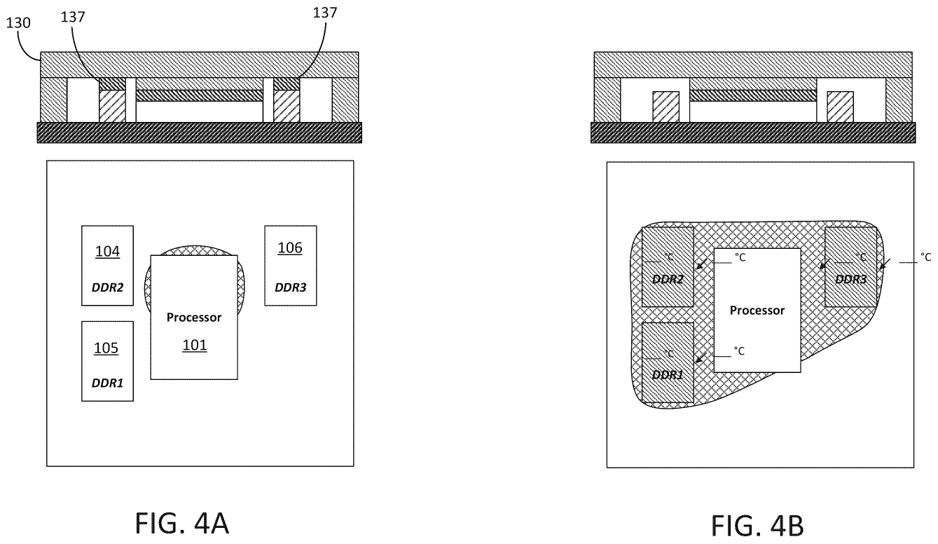

FIG. 4A and FIG. 4B illustrate example structures, respectively, with or without DRAM thermal interface material (TIM) implementation, which are cross-sectional views. With reference to FIG. 4A, a first configuration depicts MCM 100 implementing DRAM TIM 137, where SoC 101 may be surrounded by multiple DRAM components (e.g., DRAM 104, DRAM 105, DRAM 106) on substrate 108. When texted, thermal distribution maps have shown a substantially uniform temperature gradient across the package surface, as indicated by coloration (e.g., green) that suggests effective heat dissipation.

With reference to FIG. 4B, a second configuration depicts similar semiconductor package arrangement as FIG. 4A, but without DRAM TIM 137. When tested thermal distribution maps regions illustrated significantly elevated temperatures, such as around the DRAM areas (e.g., area around DRAM 104, DRAM 105, DRAM 106), indicated by coloration (e.g., red) that suggests less effective heat dissipation.

As disclosed, thermal interface material (TIM) may be placed on top of DRAM 104 to provide low thermal impedance path for DRAM 104, which may enable a lower Tjmax for DRAM 104 and in turn may help to improve ˜20% usable DRAM bandwidth from reduced DRAM refresh cycles. The material selection and tolerance analysis to ensure sufficient but not overflow TIM volume on DRAM may be a significant enabler. With DRAM TIM, when tested, there may be a reduction of approximately thirty degrees or more for the DRAM junction temperature. Peak junction temperature may reach the reliability limit (e.g., 110 Celsius), if no TIM is used.

With continued reference to thermal lid 130, a thicker Cu lid (e.g., pedestal overhang) on top of SoC 101 may provide lower thermal impedance and lower Tjmax for critical IPs. An intentional designed lid cavity 135 depth and overhang of pedestal 131 may optimize thermal benefit by minimizing thermal interface material (TIM) bond line thickness or compensate TIM delamination at SoC die edge, a commonly observed degradation after reliability stressing. The selection of TIM for SoC 101 may be modeled and characterized in order to balance thermal benefit and mechanical stress from chip-package-interaction.

With reference to TIM, microfilm insulation, such as Ajinomoto Build-up Film (ABF) based build up substrate may be selected. Bill of materials (BOM), stackup, or area may be selected based on high speed Serializer/Deserializer (SerDes) signal loss requirement, DDR and high speed SerDes signal and power fan-out requirement and core IP power delivery requirement, or ball grid array requirement for ball count/pin map and ball pitch, among other things.

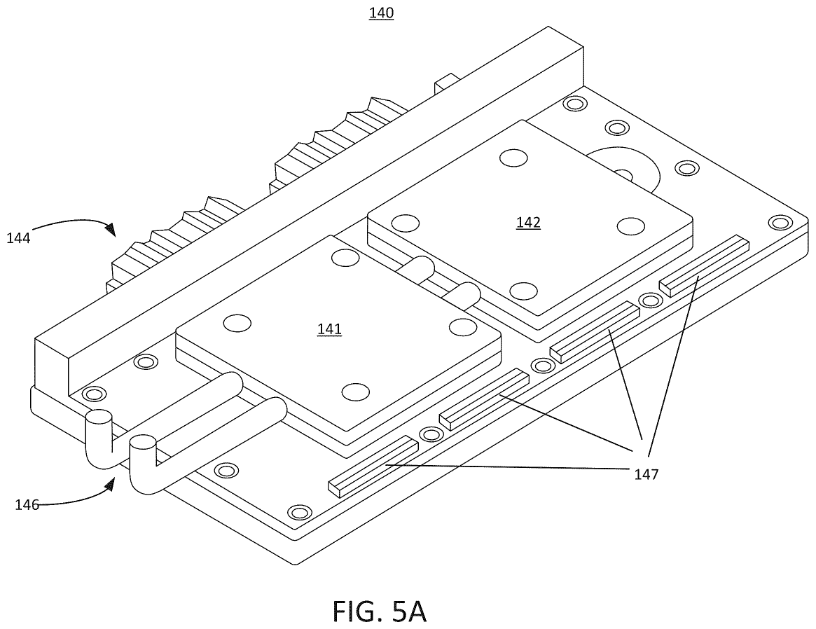

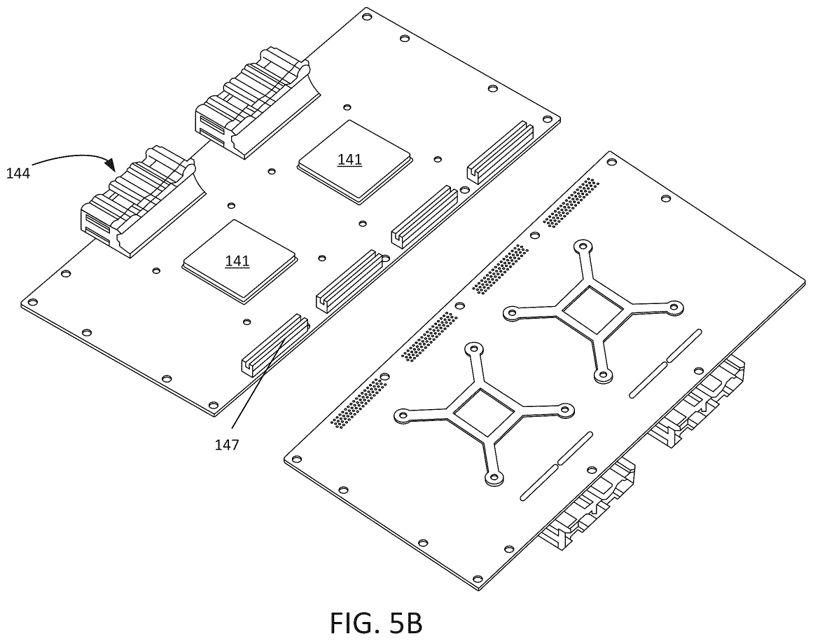

FIG. 5A illustrates a perspective view of an example test board apparatus 140 (e.g., liquid cooling cold plate) that may be associated with a MCM thermal-mechanical testing vehicle (TMTV). FIG. 5B illustrates a perspective view of test board apparatus 140 opened. In order to qualify MCM 100 in some instances for an automotive grade ADAS component, a combo thermal and mechanical daisy chain testing vehicle, namely thermal-mechanical testing vehicle (TMTV), may be used to mimic thermal, mechanical, and reliability aspects of a fully functional MCM on ADAS system board with full thermal/mechanical enclosure, which is further disclosed herein.

FIG. 5A is a perspective view of test board apparatus 140, illustrating a top surface of a substrate with mounting region 141 and mounting region 142, connectors 144 (e.g., power or signal connectors) disposed along a first edge, thermal management features, and thermal monitoring elements integrated into the substrate surface. FIG. 5B is an exploded perspective view of test board apparatus 140 showing multiple integrated components. Mounting region 141 and mounting region 142 are configured to receive semiconductor components. Connectors 144 may include a plurality of pins configured for power delivery. The thermal management features may include fluid channel 146 configured for coolant circulation. Thermal monitoring elements 147 may be disposed proximate to mounting region 141 or mounting region 142, wherein the thermal monitoring elements 147 may be configured to measure temperature distributions across the mounting regions. Test board apparatus 140 may be configured to evaluate thermal performance parameters which may include junction temperatures, thermal resistance, or power delivery characteristics of multi-chip semiconductor packages mounted thereon.

Thermal design and characterization for the TMTV 140, as disclosed herein, may affect the die, package, PCB, liquid cooling cold plate, external power suppliers, or data acquisition system. With reference to the die, heaters and sensors may be designed to be embedded into a 2-layer metal daisy chain silicon. The placement of heaters and sensors may be based on SoC IP power consumption and heat map.

Package substrate and PCB design features may be specified to provide low thermal resistance path, while PCB edge power and sensing pin connectors may be selected to meet the requirement.

The liquid cooling based cold plate may be designed for TMTV 140 so SoC and DRAM thermal may be characterized with respect to liquid coolant flow rate and temperature designated by an automobile user condition.

Other thermal characterization components may be designed and specified, such as chiller, flow meter, pressure transducer, etc. The thermal characterization plan may be formulated to characterize SoC junction temperature at different user conditions, such as full mission mode, process mode, or gear guard security mode, among other modes which may be for on-road or off-road driving.

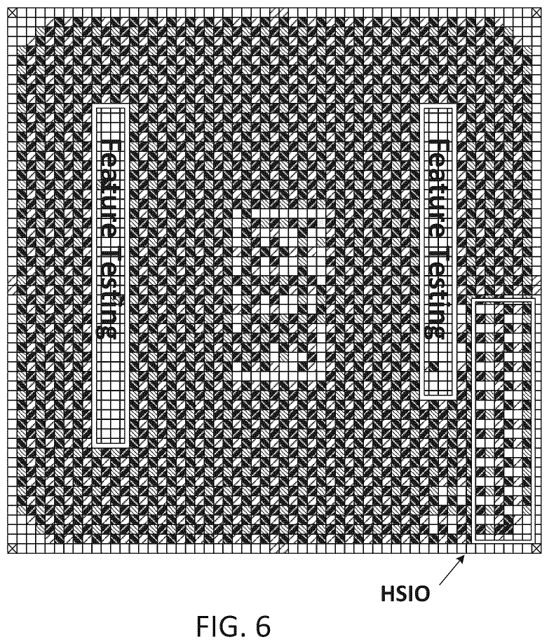

MCM technology development may leverage mechanical daisy chain features in the TMTV 140, among other features, to evaluate connectivity and reliability from die to substrate to PCB. The daisy chain designs may mimic functional paths while enabling high-resolution testing capabilities across multiple package interfaces, as shown in FIG. 6 through FIG. 9.

With reference to FIG. 6, Table 2 provides an example TMTV design feature summary matrix, mapping out the various test structures across the package. This example may include bump daisy chains (60 balls total) distributed across peripheral and core regions, multiple stacked via configurations, monitor points, die crack sensors, and specialized DDR connection test structures. FIG. 6 illustrates an example schematic view of daisy chain connection at ball grid array level. The example layout diagram features testing regions arranged in a grid pattern, with designated HSIO (High-Speed Input/Output) regions indicated.

TABLE 2

| | | # of | |
|---|---|---|---|
| Part | Test structure | Balls | Details |
| Die | Bump daisy chain | 60 | (13 peri regions + 2 core |
| | | | regions) × 2 chains × 2 balls |
| Die | A0 L1-L4 stacked vias | 20 | 5 regions × 2 chains × 2 balls |
| Die | A0 L2-L5 stacked vias | 16 | 4 regions × 2 chains × 2 balls |
| Die | Conner bump + stack | 8 | 4 regions × 1 chains × 2 balls |
| | via | | |
| Die | Monitor In/Out | 104 | 26 regions × 4 balls |
| Die | Die Crack Sensor | 8 | 4 regions × 2 balls |
| BGA | Capacitor | 4 | 1 region × 4 balls |
| BGA | DRAM BGA DC | 18 | 3 DRAMs × 3 chains × 2 balls |
| BGA | L4 20/20 DDR | 8 | 2 regions × 2 chains × 2 balls |
| | connection - 1 | | |
| BGA | L4 20/20 DDR | 4 | 1 regions × 2 chains × 2 balls |
| | connection - 2 | | |
| BGA | L2 DDR traces (Right, | 4 | 2 regions (right, left) × 1 chain × |
| | Left) | | 2 balls |
| BGA | L4 DDR traces (Right, | 4 | 2 regions (right, left) × 1 chain × |
| | Left) | | 1 ball |

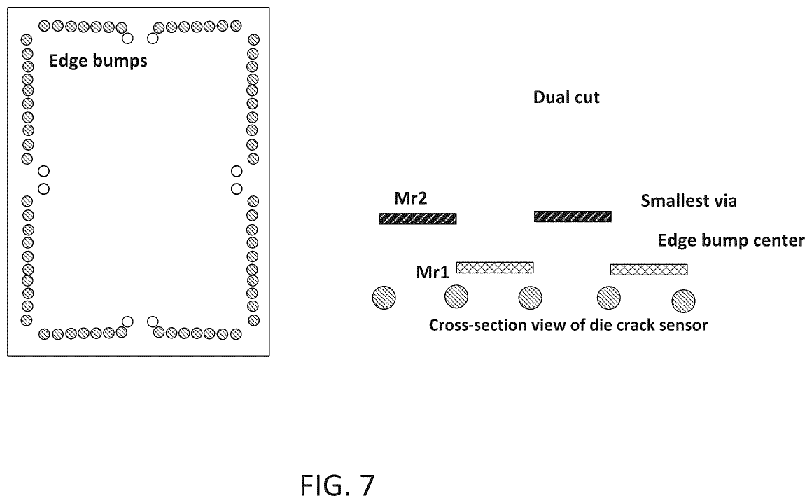

FIG. 7 illustrates an example die crack sensor implementation, showing a daisy chain configuration between metal layers Mr1 and Mr2. In an example, the sensor design incorporates precise dimensional controls including minimum line widths of approximately 0.45 μm, via diameters of approximately 0.41 μm, and seal ring spacing of approximately 0.225 μm. This configuration, combined with post-dicing optical inspection, may enable monitoring of potential die crack formation during reliability testing.

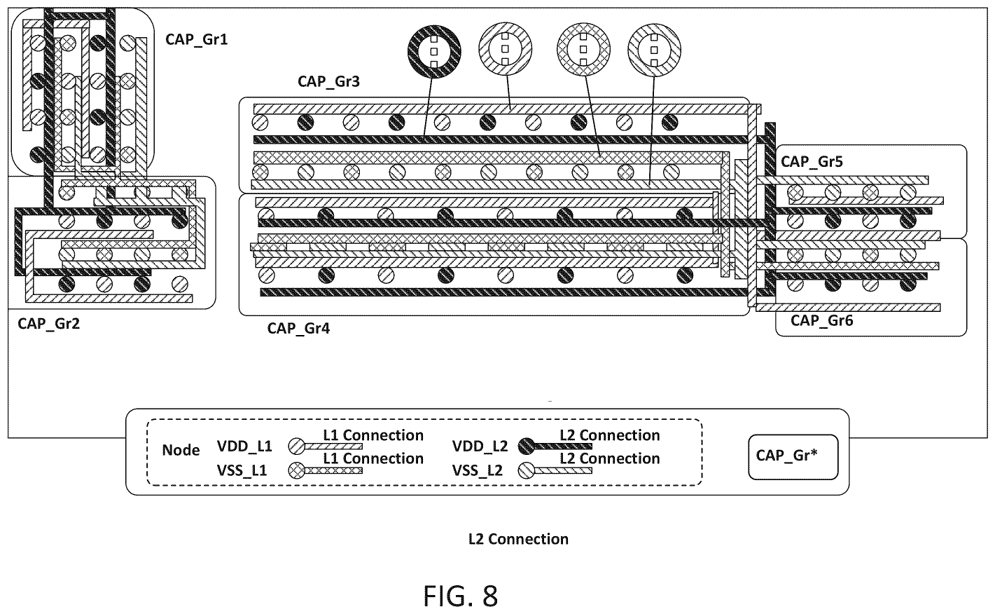

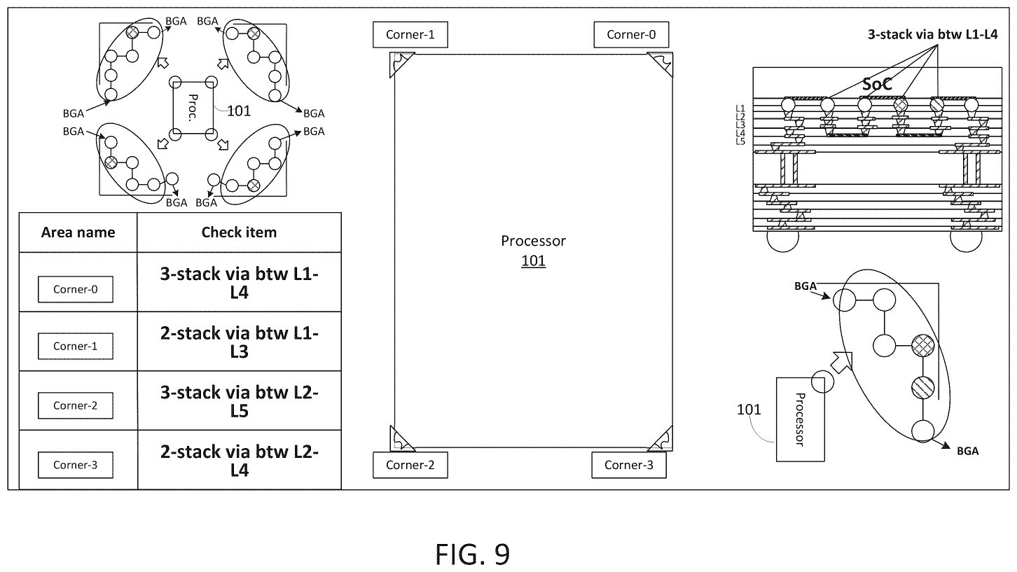

FIG. 8 illustrates an example capacitor test structure layout and verification methodology. The design may include designated test regions with specific connectivity and inspection criteria, which may allow for evaluation of capacitor functionality, shorts, or overall capacitance characteristics across the package.

FIG. 9 illustrates an example die corner stress sensor design through flip chip bumps and underneath stack vias in flip chip substrate. FIG. 9 presents the corner bump and stack via implementation strategy, featuring varied configurations of stacked vias between different layer combinations (L1-L4, L1-L3, L2-L5, L2-L4) at each corner of the processor die. This design may enable monitoring of mechanical stress effects and electrical connectivity at what may be considered significant package locations.

The daisy chains were tested based on its resistance target and acceptable resistance shift range during MCM substrate manufacturing and die assembly process so as to report out time 0 yield loss, as well as component and board level reliability stressing fall out, categorized by per daisy chain coverage. Failed or marginally passed daisy chain structures were then analyzed by electrical and physical failure analysis techniques to find root cause and solution fix, these learnings are applied to a full functional chip packaging design and BOM selection.

Multiple MCM footprint was designed into a product mimic ADAS board, as shown in FIG. 5B, board stackup and BOM follows product requirement, besides two MCM components, edge connectors are placed for supplying power for thermal testing, and signal channel for daisy chain resistance testing during system level reliability in-situ and ex-situ stressing. The stressing conditions may be constructed for designated system requirements, and this TMTV 140 set up is capable to perform full scale thermal characterization and reliability testing including power temperature cycling, shock, vibration, temperature cycle, or temperature humidity, among other things.

A system enclosure may include liquid cool cold plate. A backside metal based stiffer may be designed to enable force controlled cold plate fastening mechanism, which may be critical to ensure minimal TIM2 thickness (the thermal interface between cold plate and MCM) and thus lower thermal impedance path from a full functional MCM to external cooling system, otherwise, SoC Tjmax penalty is estimated to be up to 10 C.

The methods, systems, or apparatuses disclosed herein may be incorporated into electric vehicles or other devices. Multi-chip modules (MCMs) and thermal-mechanical testing vehicles (TMTVs) are disclosed herein. An MCM may include dynamic random access memories (DRAMs) and a system-on-chip (SoC), where the DRAMs and the SoC are integrated into a single ball grid array component for various applications. The DRAMs may be placed symmetrically around the SoC, with some implementations resembling a butterfly floor plan. When the DRAMs are placed approximately symmetrically (or radially distributed) around the SoC it may create a butterfly floor plan or similar thereto. The MCM may further include a thermal lid, which may be constructed from nickel and copper with a pedestal design. Applications of the MCM may include integration into vehicles (e.g., electric vehicles) or use in autonomous driving systems. A TMTV may include a thermal and mechanical daisy chain testing vehicle that simulates the thermal, mechanical, and reliability aspects of an MCM on an advanced driver assistance system (ADAS) board with a thermal or mechanical enclosure. Additionally, a TMTV may include a die, a package substrate, a liquid cooling cold plate, or a data acquisition system. Other TMTV components may include a chiller, flow meter, or pressure transducer.

A test apparatus and associated features are disclosed herein. A test apparatus may include a substrate having a first mounting region and a second mounting region configured to receive semiconductor components; a plurality of connectors positioned along a first edge of the substrate, the connectors may include a plurality of pins configured for power or signal delivery; a plurality of fluid channels integrated into the substrate, the fluid channels may be configured for coolant circulation; a plurality of thermal monitoring elements disposed proximate to the first and second mounting regions, the thermal monitoring elements may be configured to measure temperature distributions; or a plurality of alignment features configured to secure the thermal solution to the substrate while maintaining a predetermined contact pressure with the semiconductor components. The thermal monitoring elements may include temperature sensors configured to measure junction temperatures of the semiconductor components and may be configured to measure thermal resistance between the semiconductor components and the thermal solution. The plurality of connectors may include a first connector configured for power delivery or a second connector configured for signal transmission. The plurality of fluid channels may include an inlet port configured to receive coolant, an outlet port configured to discharge coolant, or a plurality of fluid passages connecting the inlet port to the outlet port. There may be a thermal interface layer disposed between the mounting regions and a thermal solution, the thermal interface layer may be configured to provide thermal coupling between the semiconductor components and the thermal solution. All combinations (including the removal or addition of elements) in this paragraph and the above paragraphs arc contemplated in a manner that is consistent with the other portions of the detailed description.

A reference to an element in the singular is not intended to mean one and only one unless specifically so stated, but rather one or more. For example, “a” module may refer to one or more modules. An element proceeded by “a,” “an,” “the,” or “said” does not, without further constraints, preclude the existence of additional same elements.

Headings and subheadings, if any, are used for convenience only and do not limit the invention. The word exemplary is used to mean serving as an example or illustration. To the extent that the term include, have, or the like is used, such term is intended to be inclusive in a manner similar to the term comprise as comprise is interpreted when employed as a transitional word in a claim. Relational terms such as first and second and the like may be used to distinguish one entity or action from another without necessarily requiring or implying any actual such relationship or order between such entities or actions.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A phrase “at least one of” preceding a series of items, with the terms “and” or “or” to separate any of the items, modifies the list as a whole, rather than each member of the list. The phrase “at least one of” does not require selection of at least one item; rather, the phrase allows a meaning that includes at least one of any one of the items, and/or at least one of any combination of the items, and/or at least one of each of the items. By way of example, each of the phrases “at least one of A, B, and C” or “at least one of A, B, or C” refers to only A, only B, or only C; any combination of A, B, and C; and/or at least one of each of A, B, and C.

It is understood that the specific order or hierarchy of steps, operations, or processes disclosed is an illustration of exemplary approaches. Unless explicitly stated otherwise, it is understood that the specific order or hierarchy of steps, operations, or processes may be performed in different order. Some of the steps, operations, or processes may be performed simultaneously. The accompanying method claims, if any, present elements of the various steps, operations or processes in a sample order, and are not meant to be limited to the specific order or hierarchy presented. These may be performed in serial, linearly, in parallel or in different order. It should be understood that the described instructions, operations, or systems can generally be integrated together in a single software/hardware product or packaged into multiple software/hardware products.

In one aspect, a term coupled or the like may refer to being directly coupled. In another aspect, a term coupled or the like may refer to being indirectly coupled.

Terms such as top, bottom, front, rear, side, horizontal, vertical, and the like refer to an arbitrary frame of reference, rather than to the ordinary gravitational frame of reference. Thus, such a term may extend upwardly, downwardly, diagonally, or horizontally in a gravitational frame of reference.

The disclosure is provided to enable any person skilled in the art to practice the various aspects described herein. In some instances, well-known structures and components are shown in block diagram form in order to avoid obscuring the concepts of the subject technology. The disclosure provides various examples of the subject technology, and the subject technology is not limited to these examples. Various modifications to these aspects will be readily apparent to those skilled in the art, and the principles described herein may be applied to other aspects.

All structural and functional equivalents to the elements of the various aspects described throughout the disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim clement is to be construed under the provisions of 35 U.S.C. § 112(f), unless the element is expressly recited using the phrase “means for” or, in the case of a method claim, the element is recited using the phrase “step for”.

Those of skill in the art would appreciate that the various illustrative blocks, modules, elements, components, methods, and algorithms described herein may be implemented as hardware, electronic hardware, computer software, or combinations thereof. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language of the claims and to encompass all legal equivalents. Notwithstanding, none of the claims are intended to embrace subject matter that fails to satisfy the requirements of the applicable patent law, nor should they be interpreted in such a way.

What is claimed is:

1. A multi-chip-module (MCM) comprising:
dynamic random access memories (DRAMs); and
system-on-chip (SoC), wherein the DRAMs and the SoC are integrated as one integral ball grid array component for an application.

2. The MCM of claim 1, wherein the DRAMs are placed approximately symmetrically around the SoC.

3. The MCM of claim 1, wherein the DRAMs are located in a manner that creates a butterfly floor plan.

4. The MCM of claim 1, further comprising a thermal lid.

5. The MCM of claim 4, wherein the thermal lid comprises nickel and copper, and wherein the thermal lid is of a pedestal design.

6. The MCM of claim 4, wherein the thermal lid comprises nickel plated copper.

7. The MCM of claim 4, wherein the thermal lid further comprises a first material and a second material, wherein the first material is used to provide a threshold thermal conductivity.

8. The MCM of claim 7, wherein the second material is used to provide protection against a threshold level of corrosion.

9. The MCM of claim 7, wherein the first material comprises copper-tungsten.

10. The MCM of claim 7, wherein the first material comprises copper-molybdenum.

11. The MCM of claim 4, further comprising thermal interface material (TIM), wherein the TIM is placed over one or more of the DRAMs.

12. The MCM of claim 11, wherein the TIM comprises a specialized polymer film.

13. The MCM of claim 4, wherein the thermal lid comprises a cavity.

14. The MCM of claim 4, wherein the thermal lid comprises a pedestal over the SoC.

15. The MCM of claim 4, wherein the thermal lid comprises a pedestal over one or more of the DRAMs.

16. The MCM of claim 1, wherein the MCM is integrated into an electric vehicle.

17. The MCM of claim 1, wherein the application is an autonomous driving application.

18. A thermal-mechanical testing vehicle (TMTV) comprising:
a die;
a package substrate; and
a liquid cooling cold plate.

19. The TMTV of claim 18, further comprising:
a chiller; and
a flow meter.

20. The TMTV of claim 19, further comprising a pressure transducer.
